(19) United States
(12) Patent Application Publication
(10) Pub. No.: US 2024/0079847 A1
(43) Pub. Date: Mar. 7, 2024

(54) SEMICONDUCTOR LIGHT EMITTING DEVICE

(71) Applicant: ROHM CO., LTD., Kyoto-shi (JP)

(72) Inventor: Tomoichiro TOYAMA, Kyoto-shi (JP)

(21) Appl. No.: 18/505,772

(22) Filed: Nov. 9, 2023

Related U.S. Application Data
(63) Continuation of application No. PCT/JP2022/019010, filed on Apr. 27, 2022.

(30) Foreign Application Priority Data
May 14, 2021 (JP) 2021-082074
Mar. 29, 2022 (JP) 2022-053889

(51) Int. Cl. H01S 5/02234

(52) U.S. Cl. CPC H01S 5/02234; H01S 5/183

(57) ABSTRACT

A semiconductor light emitting device includes a semiconductor laser element including a light emitting surface from which a laser beam is emitted and a light-transmissive resin member covering the light emitting surface of the semiconductor laser element. The semiconductor light emitting device further includes a diffusing agent mixed into the resin member.

### BACKGROUND

### 1. Field

The following description relates to a semiconductor light emitting device.

### 2. Description of Related Art

A semiconductor light emitting device includes a semiconductor light emitting element as a light source. Examples of a typical semiconductor light emitting element include a semiconductor laser element of a vertical cavity surface emitting laser (VCSEL) and a light emitting diode (LED). Japanese Laid-Open Patent Publication No. 2013-41866 describes a semiconductor light emitting device that uses an LED.

### BRIEF DESCRIPTION OF THE DRAWINGS

FIG. 1 is a schematic plan view showing a first embodiment of an exemplary semiconductor light emitting device.

FIG. 2 is a cross-sectional view taken along line 2-2 in FIG. 1.

FIG. 3 is a cross-sectional view taken along line 3-3 in FIG. 1.

FIG. 4 is a schematic perspective view showing a cross-sectional structure of a semiconductor laser element.

FIG. 5 is an enlarged cross-sectional view of a portion of the semiconductor laser element shown in FIG. 4.

FIG. 6 is a graph showing the directivity of a semiconductor light emitting device (first sample) that does not include a resin member and a diffusing agent.

FIG. 7 is a graph showing the directivity of a semiconductor light emitting device (second sample) in which the mixture ratio of the diffusing agent to the resin member is 5%.

FIG. 8 is a graph showing the directivity of a semiconductor light emitting device (third sample) in which the mixture ratio of the diffusing agent to the resin member is 20%.

FIG. 9 is a graph showing the directivity of a semiconductor light emitting device (fourth sample) in which the mixture ratio of the diffusing agent to the resin member is 40%.

FIG. 10 is a graph showing the directivity of a semiconductor light emitting device (fifth sample) in which the mixture ratio of the diffusing agent to the resin member is 60%.

FIG. 11 is a graph showing the relationship between the mixture ratio of the diffusing agent and the radiation intensity of the semiconductor light emitting device.

FIG. 12 is a graph showing the relationship between the mixture ratio of the diffusing agent and the optical output of the semiconductor light emitting device.

FIG. 13 is a graph showing the directivity of a semiconductor light emitting device (sixth sample) in a second embodiment in a short-side direction when the amount of the resin member is a first amount A1 and the mixture ratio of the diffusing agent is 30%.

FIG. 14 is a graph showing the directivity of the sixth sample in a long-side direction.

FIG. 15 is a graph showing the directivity of the semiconductor light emitting device (seventh sample) in the second embodiment in a short-side direction when the amount of the resin member is the first amount A1 and the mixture ratio of the diffusing agent is 60%.

FIG. 16 is a graph showing the directivity of the seventh sample in the long-side direction.

FIG. 17 is a graph showing the directivity of the semiconductor light emitting device (eighth sample) in the second embodiment in the short-side direction when the amount of the resin member is a second amount A2 (A2>A1) and the mixture ratio of the diffusing agent is 60%.

FIG. 18 is a graph showing the directivity of the eighth sample in the long-side direction.

FIG. 19 is a graph showing the directivity of a semiconductor light emitting device (ninth sample) that includes the first amount A1 of the resin member and does not include the diffusing agent.

FIG. 20 is a graph showing the directivity of the ninth sample in the long-side direction.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Embodiments of a semiconductor light emitting device according to the present disclosure will be described below with reference to the drawings.

In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

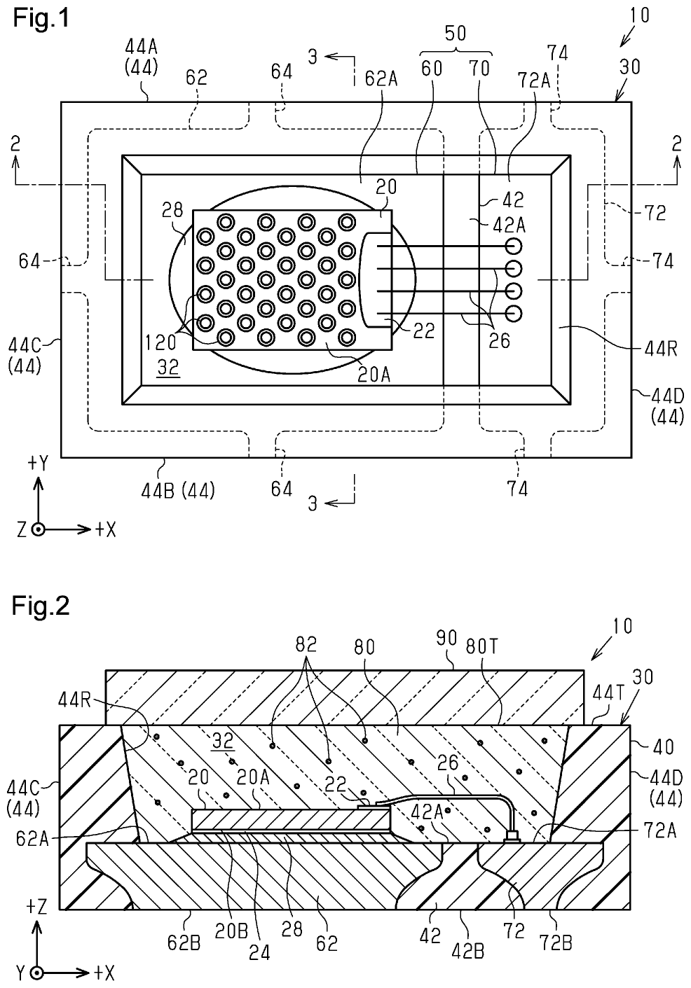

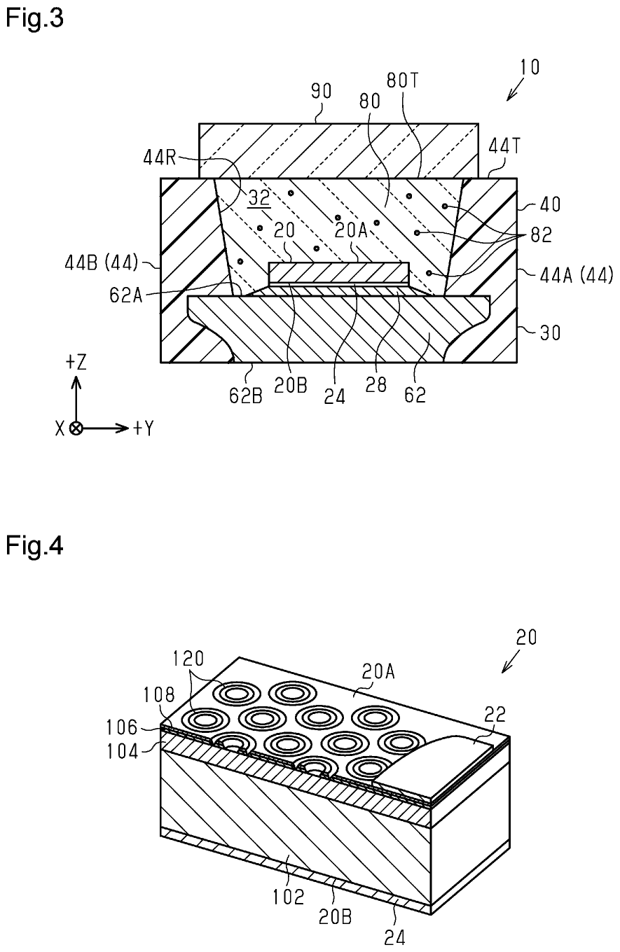

A first embodiment of a semiconductor light emitting device 10 will now be described. FIG. 1 is a schematic plan view showing an example of the semiconductor light emitting device 10. FIG. 2 is a cross-sectional view taken along line 2-2 in FIG. 1. FIG. 3 is a cross-sectional view taken along line 3-3 in FIG. 1.

The term “plan view” used in the present disclosure refers to a view of the semiconductor light emitting device 10 in the Z-axis direction when the XYZ-axes are orthogonal to each other as shown in FIGS. 1 to 3. In the semiconductor light emitting device 10 shown in FIGS. 1 to 3, the +Z direction defines the upper side, and the −Z direction defines the lower side. The +X direction defines the right, and the −X direction defines the left. Unless otherwise specified, “plan view” refers to a view of the semiconductor light emitting device 10 taken from above in the Z-axis direction.

Structure of Semiconductor Light Emitting Device 10

As shown in FIGS. 1 to 3, the semiconductor light emitting device 10 includes a semiconductor laser element 20, which is a light emitting element, and a support 30 supporting the semiconductor laser element 20. The semiconductor laser element 20 is a laser diode that emits light having a predetermined wavelength range and is used as a light source of the semiconductor light emitting device 10. The structure of the semiconductor laser element 20 is not limited. In the first embodiment, a vertical cavity surface emitting laser (VCSEL) element is used. Light is emitted from the semiconductor laser element 20 generally in the +Z-direction.

The structure and shape of the support 30 are not limited. In the first embodiment, the support 30 includes a base 40 and a conductive portion 50 and is box-shaped and open in one direction (+Z-direction). The base 40 and the conductive portion 50 form an accommodation portion 32 for the semiconductor laser element 20. In an example, the base 40 is formed from a glass-epoxy resin, which is an example of thermosetting resin, a nylon or a liquid crystal polymer, which are examples of thermoplastic resin, or aluminum nitride (AlN) or alumina (Al₂O₃), which are examples of ceramic. However, the material of the base 40 is not limited to those described. In an example, the conductive portion 50 is formed from a conductive material such as copper (Cu).

The structure and shape of the conductive portion 50 are not limited. In the first embodiment, the conductive portion 50 is formed of a lead frame and includes a first conductive portion 60 and a second conductive portion 70. As shown in FIG. 1, the first conductive portion 60 includes a mount 62 and a plurality of (for example, three) extensions 64 extending from side edges of the mount 62 (in the example shown in FIG. 1, in direction parallel to the XY-plane). In the same manner, the second conductive portion 70 includes a mount 72 and a plurality of (for example, three) extensions 74 extending from side edges of the mount 72.

In an example, the mount 62 is rectangular in plan view and includes a front surface 62A, used as a mount surface, and a back surface 62B opposite to the front surface 62A. In the same manner, in an example, the mount 72 is rectangular in plan view and includes a front surface 72A, used as a mount surface, and a back surface 72B opposite to the front surface 72A. The front surfaces 62A and 72A of the mounts 62 and 72 are located at the bottom surface of the accommodation portion 32. The back surfaces 62B and 72B of the mounts 62 and 72 are exposed from an outer surface (back surface) of the base 40.

The structure of the base 40 is not limited. In the first embodiment, the base 40 includes a separator 42 and a peripheral wall portion 44. The separator 42 is formed integrally with the peripheral wall portion 44. There is no physical boundary between the separator 42 and the peripheral wall portion 44.

The separator 42 is arranged between the mount 62 (first conductive portion 60) and the mount 72 (second conductive portion 70) and maintains a state that insulates the mounts 62 and 72 from each other. The separator 42 includes a front surface 42A and a back surface 42B opposite to the front surface 42A. The front surface 42A of the separator 42 is flush with the front surfaces 62A and 72A of the mounts 62 and 72 and is located at the bottom surface of the accommodation portion 32. The back surface 42B of the separator 42 is flush with the back surfaces 62B and 72B of the mounts 62 and 72 and is exposed from the outer surface (back surface) of the base 40.

The peripheral wall portion 44 surrounds the semiconductor laser element 20. The accommodation portion 32 of the semiconductor laser element 20 is defined by the peripheral wall portion 44. In the first embodiment, the accommodation portion 32 is an inner cavity defined by the peripheral wall portion 44, the mounts 62 and 72, and the separator 42.

In an example, the peripheral wall portion 44 is rectangular-frame-shaped in plan view and includes first to fourth side walls 44A, 44B, 44C, and 44D. The contour of the peripheral wall portion 44 is not limited and may be a circle in plan view or a polygon (e.g., octagon) in plan view. The first side wall 44A and the second side wall 44B are opposed to each other. The third side wall 44C and the fourth side wall 44D are opposed to each other. As shown in FIGS. 1 to 3, in the first embodiment, the first, second, and third side walls 44A, 44B, and 44C cover three of the side edges of the mount 62. End surfaces of the extensions 64 are exposed from outer surfaces of the first, second, and third side walls 44A, 44B, and 44C. The first, second, and fourth side walls 44A, 44B, and 44D cover three of the side edges of the mount 72. End surfaces of the extensions 74 are exposed from outer surfaces of the first, second, and fourth side walls 44A, 44B, and 44D.

The peripheral wall portion 44 is used as a reflector. In the first embodiment, the peripheral wall portion 44 includes an inner surface 44R, which is used as a reflection surface. The inner surface 44R is inclined so that the open width of the accommodation portion 32 is decreased from the open end of the accommodation portion 32 toward the bottom surface of the accommodation portion 32 (front surfaces 62A, 72A, and 42A).

The semiconductor laser element 20 includes a front surface 20A, a back surface 20B opposite to the front surface 20A, a first electrode 22, and a second electrode 24. The front surface 20A is used as a light emitting surface from which a laser beam is emitted. The first electrode 22 is formed on the front surface 20A. The second electrode 24 is formed on the back surface 20B. In the first embodiment, the first electrode 22 is an anode electrode. The second electrode 24 is a cathode electrode.

In an example, the first electrode 22 is formed from metal and is connected (wire-bonded) to the front surface 72A of the mount 72 by wires 26. The material of the wires 26 is not limited and may be, for example, metal such as gold (Au). In the example shown in FIG. 1, the four wires 26 are arranged next to each other. However, the number and arrangement of the wires 26 are not limited.

In an example, the second electrode 24 is formed from metal and is connected (die-bonded) to the front surface 62A of the mount 62 by a conductive bonding member 28. The material of the conductive bonding member 28 is not limited and may be, for example, a conductive material such as solder or a paste containing metal such as silver (Ag).

As shown in FIGS. 2 and 3, in the first embodiment, the semiconductor light emitting device 10 further includes a light-transmissive resin member 80 that covers the front surface 20A (light outputting surface) of the semiconductor laser element 20 and a diffusing agent 82 mixed into the resin member 80.

The resin member 80 fills the accommodation portion 32 of the support 30 and entirely covers the semiconductor laser element 20, the first electrode 22, and the wires 26. In an example, the resin member 80 fills the accommodation portion 32 to the same height as an upper end surface 44T of the peripheral wall portion 44 and includes an upper surface 80T (light outputting surface) that is flush with the upper end surface 44T. However, the upper surface 80T of the resin member 80 does not necessarily have to be a completely flat surface and may be slightly recessed. The upper surface 80T (light outputting surface) of the resin member 80 is located at the open end of the accommodation portion 32. The resin member 80 has the role of refracting and transmitting the light emitted from the semiconductor laser element 20. The material of the resin member 80 is not limited and may be, for example, a transparent resin such as a silicone resin. A fluorescence substance may be added to the resin member 80.

The diffusing agent 82 dispersed as fine particles in the resin member 80. The diffusing agent 82 is mixed into the resin member 80 at a predetermined mixture ratio. In the first embodiment, the diffusing agent 82 is mixed into the resin member 80 to scatter light from the semiconductor laser element 20 to a position that differs from a peak position of optical output of the semiconductor laser element 20. In an example, the diffusing agent 82 is evenly dispersed in the resin member 80.

The directivity of light emitted from the semiconductor laser element 20 is greater than that of a light emitting diode (LED). In the first embodiment, the semiconductor laser element 20, which is configured as a VCSEL element, emits light in the +Z-direction, which is substantially perpendicular to the front surface 20A (light outputting surface). Thus, for example, when the resin member 80 and the diffusing agent 82 are not present, the light emitted from the semiconductor laser element 20 in the +Z-direction scatters subtly in a direction parallel to the XY plane (i.e., the front surface 20A used as light emitting surface) and travels substantially straight in the +Z-direction.

The diffusing agent 82 reflects (scatters) light in the interface between the resin member 80 and the diffusing agent 82 to diffuse the light in the resin member 80. Thus, the diffusing agent 82 has the role of diffusing the light, emitted from the semiconductor laser element 20, in the resin member 80 to increase the directivity angle of the light when emitted from the upper surface 80T of the resin member 80 (ultimately the semiconductor light emitting device 10).

The material of the diffusing agent 82 is not limited and may be, for example, silica or other glass materials. In the first embodiment, a spherical silica filler is used as the diffusing agent 82. The particle size of the diffusing agent 82 is not limited. In an example, the particle size is sufficiently smaller than the wavelength of light emitted from the semiconductor laser element 20 so that Rayleigh scattering predominantly occurs. The particle size of the diffusing agent 82 is, for example, selected in a range of 0.001 μm or greater and 50 μm or less.

The mixture ratio of the diffusing agent 82 to the resin member 80 (hereafter, may be simply referred to as “the mixture ratio of the diffusing agent 82” or “the mixture ratio”) is not limited and may be greater than 0% and less than 100%. As the mixture ratio of the diffusing agent 82 is increased, the directivity angle of light emitted from the semiconductor light emitting device 10 is increased. When the upper limit of the mixture ratio of the diffusing agent 82 is limited to a predetermined value, a considerable decrease in the optical output and the radiation intensity of the semiconductor light emitting device 10 is avoided. In an example, in the first embodiment, the mixture ratio of the diffusing agent 82 is selected preferably from a range that is greater than 0% and less than or equal to 60% and more preferably from a range that is greater than or equal to 20% and less than or equal to 60%. The relationship between the mixture ratio of the diffusing agent 82 and the optical characteristics of the semiconductor light emitting device 10 will be described later.

In the first embodiment, the diffusing agent 82 has a smaller thermal expansion coefficient than the resin member 80. In this case, the diffusing agent 82, mixed into the resin member 80, decreases thermal stress that occurs in the resin member 80 in comparison with when the accommodation portion 32 is filled with only the resin member 80. This limits breakage of the wires 26 or the like caused by thermal stress of the resin member 80.

The semiconductor light emitting device 10 further includes a light diffusion plate 90 that covers the upper surface 80T (light outputting surface) of the resin member 80. The light diffusion plate 90 is not shown in FIG. 1 for clarity. In an example, the light diffusion plate 90 is a flat plate and is rectangular in plan view. The light diffusion plate 90 is bonded to the upper end surface 44T of the peripheral wall portion 44 by adhesive (not shown). The material of the light diffusion plate 90 is not limited and may be, for example, a light-transmissive resin such as polycarbonate, polyester, or acrylic. The light diffusion plate 90 diffuses and transmits light emitted from the upper surface 80T of the resin member 80.

In addition to the light diffusion plate 90, a covering member that is microfabricated to obtain a desired optical characteristic may be arranged on the light diffusion plate 90. In an example, the covering member may be a transparent resin material or glass that is microfabricated to obtain the desired optical characteristic. In another example, resin may be microfabricated to obtain the desired characteristic and applied to glass.

In the example shown in FIGS. 2 and 3, in plan view, the light diffusion plate 90 is smaller in size than the base 40. However, the size of the light diffusion plate 90 may be changed in any manner. In an example, instead of entirely covering the upper surface 80T of the resin member 80, the light diffusion plate 90 may be sized to cover at least the semiconductor laser element 20 in plan view. In this case, a light-blocking member may be arranged on the upper surface 80T of the resin member 80 that is exposed from the light diffusion plate 90.

Example of Structure of Semiconductor Laser Element 20

An exemplary structure of the semiconductor laser element 20 will now be described. The structure of the semiconductor laser element 20 described below is an example and is not intended to be restrictive.

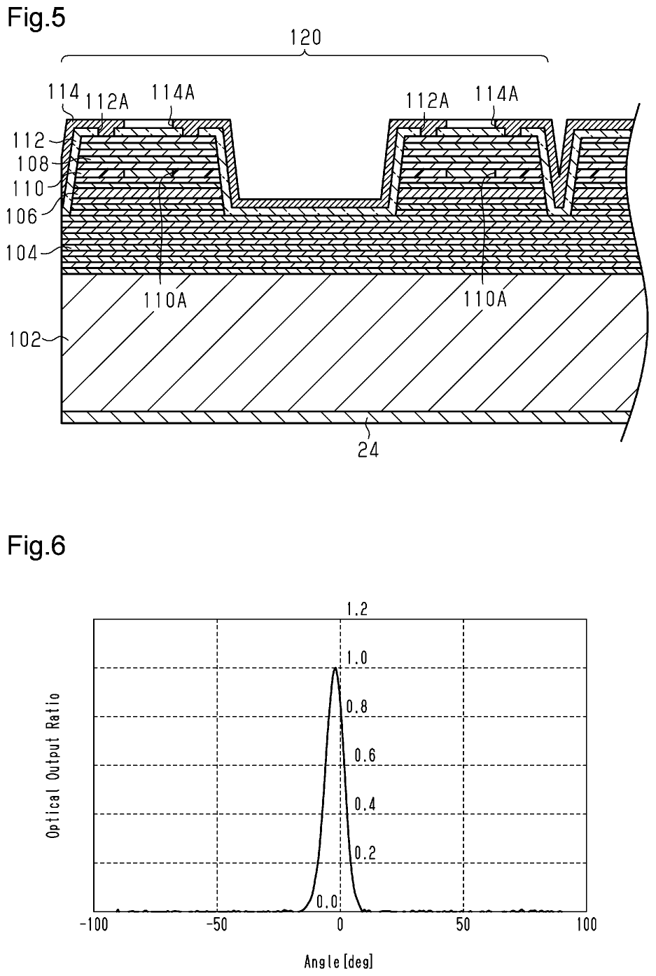

FIG. 4 is a schematic perspective view showing a cross-sectional structure of the semiconductor laser element 20. FIG. 5 is an enlarged cross-sectional view of a portion of the semiconductor laser element 20 shown in FIG. 4.

As shown in FIGS. 4 and 5, the semiconductor laser element 20 includes an element substrate 102, a first semiconductor layer 104, an active layer 106, a second semiconductor layer 108, a current confining layer 110, an insulation layer 112, and a conductive layer 114. As shown in FIG. 4, the semiconductor laser element 20 includes multiple light emitting regions 120. The light emitting regions 120 are separately arranged in a region of the front surface 20A of the semiconductor laser element 20 excluding the first electrode 22. The number of the light emitting regions 120 formed in the semiconductor laser element 20 is not limited. FIG. 5 shows an enlarged portion including one light emitting region 120.

The element substrate 102 is formed of a semiconductor. The type of semiconductor of the element substrate 102 is not limited. In an example, gallium arsenide (GaAs) may be used.

The active layer 106 is formed of a compound semiconductor that emits light having, for example, a wavelength band of 980 nm (hereafter, denoted by “λa”) through spontaneous emission and stimulated emission. The active layer 106 is arranged between the first semiconductor layer 104 and the second semiconductor layer 108. In the first embodiment, the active layer 106 has a multiple quantum well structure in which undoped GaAs well layers and undoped AlGaAs block layers (barrier layers) are alternately stacked. In an example, undoped block layers of Al_{0.35}Ga_{0.65}As and undoped well layers of GaAs are alternately stacked in two to six periods.

The first semiconductor layer 104 is typically a distributed Bragg reflector (DBR) layer and is formed on the element substrate 102. The first semiconductor layer 104 is formed of a semiconductor of a first conductive type. In the present example, the first conductive type is n-type. The first semiconductor layer 104 is configured as the DBR for efficiently reflecting light emitted from the active layer 106. In an example, the first semiconductor layer 104 is formed by stacking pairs of two AlGaAs layers differing in reflectance and having a thickness of λa/4. In an example, the first semiconductor layer 104 is formed by alternately stacking n-type Al_{0.16}Ga_{0.84}As layers having a thickness of 600 angstroms and a relatively low Al composition (low Al composition layers) and n-type Al_{0.84}Ga_{0.16}As layers having a thickness of 700 angstroms and a relatively high Al composition (high Al composition layers) in multiple periods (e.g., twenty periods). The n-type Al_{0.16}Ga_{0.84}As layers are doped with, for example, an n-type impurity (e.g., Si) at a concentration of 2×10¹⁷ cm⁻³ or greater and 3×10¹⁸ cm⁻³ or less. The n-type Al_{0.84}Ga_{0.16}As layers are doped with, for example, an n-type impurity (e.g., Si) at a concentration of 2×10¹⁷ cm⁻³ or greater and 3×10¹⁸ cm⁻³ or less.

The second semiconductor layer 108 is typically a DBR layer and is formed of a semiconductor of a second conductive type. In the present example, the second conductive type is p-type. Alternatively, the first conductive type may be p-type, and the second conductive type may be n-type. The first semiconductor layer 104 is arranged between the second semiconductor layer 108 and the element substrate 102. The second semiconductor layer 108 is configured as the DBR for efficiently reflecting light emitted from the active layer 106. In an example, the second semiconductor layer 108 is formed by stacking pairs of two AlGaAs layers differing in reflectance and having a thickness of λa/4. In an example, the second semiconductor layer 108 is formed by alternately stacking p-type Al_{0.16}Ga_{0.84}As layers having a relatively low Al composition (low Al composition layers) and p-type Al_{0.84}Ga_{0.16}As layers having a relatively high Al composition (high Al composition layers) in multiple periods (e.g., twenty periods).

The current confining layer 110 is disposed in the second semiconductor layer 108. In an example, the current confining layer 110 is formed of a layer that includes a large amount of Al and is prone to oxidation. The layer is oxidized to obtain the current confining layer 110. However, the current confining layer 110 does not necessarily have to be formed through oxidization and may be formed using another process (e.g., ion implantation). The current confining layer 110 has an opening 110A. Current flows through the opening 110A.

The insulation layer 112 is formed on the second semiconductor layer 108. The insulation layer 112 is formed of, for example, silicon dioxide (SiO₂). The insulation layer 112 has an opening 112A.

The conductive layer 114 is formed on the insulation layer 112. The conductive layer 114 is formed from a conductive material (e.g., metal). The conductive layer 114 is electrically connected to the second semiconductor layer 108 through the opening 112A in the insulation layer 112. The conductive layer 114 has an opening 114A.

Light from the active layer 106 is directly emitted to the light emitting region 120 or is reflected and then emitted to the light emitting region 120. In the present example, the light emitting region 120 is annular in plan view but is not limited to a particular shape. The light emitting region 120 is formed by stacking the second semiconductor layer 108, the current confining layer 110, the insulation layer 112, and the conductive layer 114, which are described above, and forming the opening 110A in the current confining layer 110, the opening 112A in the insulation layer 112, and the opening 114A in the conductive layer 114. In the light emitting region 120, the light from the active layer 106 is emitted through the opening 114A in the conductive layer 114.

Relationship Between Mixture Ratio of Diffusing Agent 82 and Directivity of Semiconductor Light Emitting Device 10

With reference to FIGS. 6 to 10, the relationship between the mixture ratio of the diffusing agent 82 to the resin member 80 and the directivity of the semiconductor light emitting device 10 will be described. The same reference numerals are given to those components that are the same as the corresponding components of FIGS. 1 to 5.

In the first embodiment, the directivity angle of the semiconductor light emitting device 10 is defined as an angular range (half-power width) in which the optical output of the semiconductor light emitting device 10 is 50% of the maximum value (maximum peak). In the first embodiment of the semiconductor laser element 20, the optical output of the semiconductor laser element 20 has a peak in a direction (in the first embodiment, upper vertical direction) orthogonal to the front surface 20A, or the light emitting surface. In the present disclosure, to simplify the description, the direction in which the peak of the optical output of the semiconductor laser element 20 is obtained with respect to the light emitting surface is defined as a reference direction (at reference angle of zero degrees). The reference angle may be referred to as the peak position of optical output of the semiconductor laser element 20. In FIGS. 6 to 10, the vertical axis indicates the optical output ratio of the semiconductor light emitting device 10 when the maximum value (maximum peak) of optical output of the semiconductor light emitting device 10 is 1.0.

FIGS. 6 to 10 show the directivity of the first to fifth samples (semiconductor light emitting device 10), for example, when the mixture ratio of the diffusing agent 82 is 0% (no diffusing agent 82), 5%, 20%, 40%, and 60%. In the five samples, the semiconductor light emitting device 10 does not include the light diffusion plate 90 so that the effects of the resin member 80 and the diffusing agent 82 may be evaluated. To simplify the evaluation, in the five samples, the semiconductor laser element 20 includes two light emitting regions 120. It is verified that when the number of the light emitting regions 120 is one or three or more, the evaluation results have tendencies similar to those of the five samples.

FIG. 6 shows the directivity in one direction that is evaluated using the first example of the semiconductor light emitting device 10 that does not include the resin member 80 and the diffusing agent 82, that is, when the mixture ratio of the diffusing agent 82 is 0%. When the mixture ratio of the diffusing agent 82 is 0%, the directivity angle (half-power width) is approximately 10 degrees. In the first sample, the optical output of the semiconductor light emitting device 10 includes only one peak (maximum peak) appearing near the reference angle (zero degrees). The maximum peak corresponds to the optical output peak of the semiconductor laser element 20.

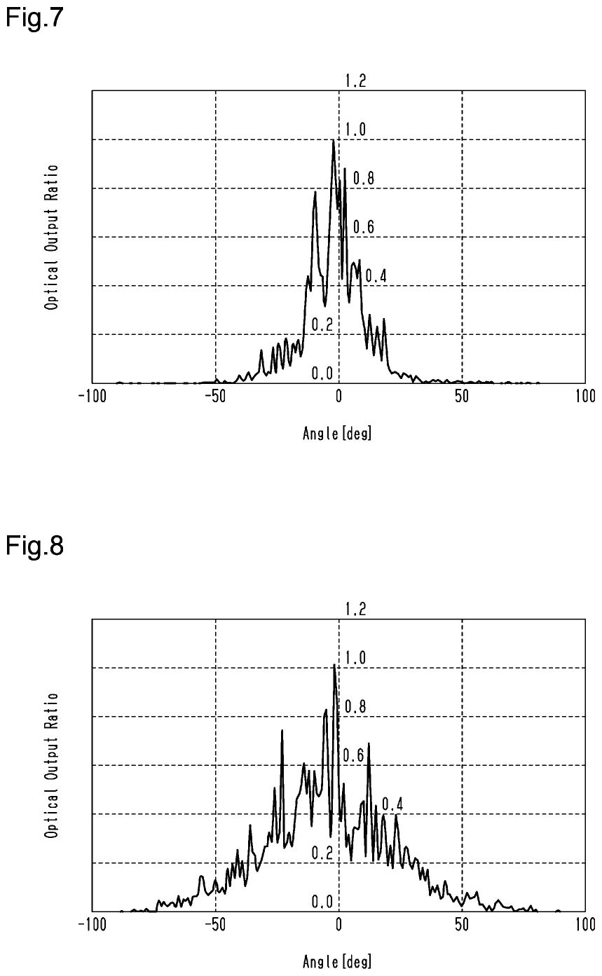

FIG. 7 shows the directivity in one direction using the second example of the semiconductor light emitting device 10 when the mixture ratio of the diffusing agent 82 to the resin member 80 is 5%. When the mixture ratio of the diffusing agent 82 is 5%, the directivity angle is approximately 20 degrees. In the second sample, the optical output of the semiconductor light emitting device 10 includes multiple peaks. The maximum peak position at which the maximum peak is output among the multiple peaks appears near the reference angle (zero degrees). The maximum peak position may be referred to as the maximum peak angle.

FIG. 8 shows the directivity in one direction using the third example of the semiconductor light emitting device 10 when the mixture ratio of the diffusing agent 82 to the resin member 80 is 20%. When the mixture ratio of the diffusing agent 82 is 20%, the directivity angle is approximately 37 degrees. In the third sample, the optical output of the semiconductor light emitting device 10 also includes multiple peaks in the same manner as the second sample. The maximum peak position appears near the reference angle (zero degrees).

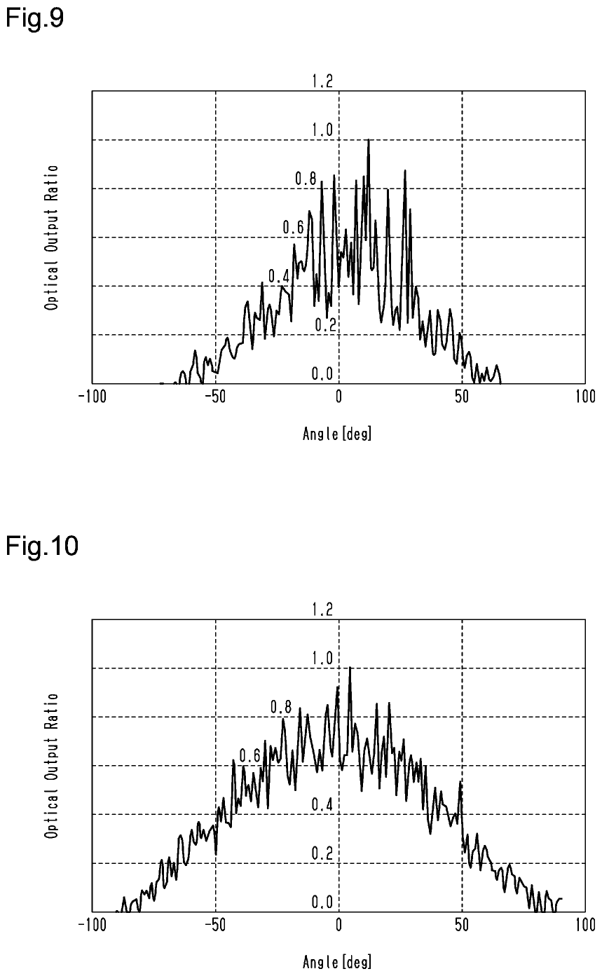

FIG. 9 shows the directivity in one direction using the fourth example of the semiconductor light emitting device 10 when the mixture ratio of the diffusing agent 82 to the resin member 80 is 40%. When the mixture ratio of the diffusing agent 82 is 40%, the directivity angle is approximately 47 degrees. In the fourth sample, the optical output of the semiconductor light emitting device 10 also includes multiple peaks in the same manner as the second and third samples. However, the maximum peak position appears in a position differing from the reference angle (zero degrees). This indicates that the maximum peak position of the semiconductor light emitting device 10 is deviated from the reference angle due to light scattering caused by the diffusing agent 82.

FIG. 10 shows the directivity in one direction using the fifth example of the semiconductor light emitting device 10 when the mixture ratio of the diffusing agent 82 to the resin member 80 is 60%. When the mixture ratio of the diffusing agent 82 is 60%, the directivity angle is approximately 88 degrees. In the fifth sample, the optical output of the semiconductor light emitting device 10 also includes multiple peaks in the same manner as the second, third, and fourth samples. However, the maximum peak position appears in a position slightly differing from the reference angle (zero degree). As described in the fourth sample, the maximum peak position of the semiconductor light emitting device 10 is deviated from the reference angle due to light scattering caused by the diffusing agent 82.

The evaluation results of the first to fifth samples shown in FIGS. 6 to 10 show that as the mixture ratio of the diffusing agent 82 increases, the directivity angle increases. As shown in FIG. 6 and described above, when the resin member 80 and the diffusing agent 82 are not included, the optical output of the semiconductor light emitting device 10 (first sample) has one peak, that is, only the optical output peak of the semiconductor laser element 20.

In contrast, as shown in FIGS. 7 to 10, when the diffusing agent 82 is mixed into the resin member 80, the light scattering caused by the diffusing agent 82 results in the optical output of the semiconductor light emitting device 10 having multiple peaks. The multiple peaks appear in a direction orthogonal to the front surface 20A (light outputting surface) of the semiconductor laser element 20 and a direction differing from the direction orthogonal to the front surface 20A (light outputting surface). The direction orthogonal to the front surface 20A (light outputting surface) is not limited to the upper vertical direction corresponding to the reference angle (zero degrees) and is intended to include angular directions slightly deviated from the reference angle.

As a result, the optical output of the semiconductor light emitting device 10 (second to fifth samples) includes multiple peaks at positions differing from the position of the maximum peak generated by the peak of optical output of the semiconductor laser element 20. Thus, in the second to fifth samples, the directivity characteristic of the semiconductor light emitting device 10 does not show a smoothly curved parabolic line. Rather, as shown in FIGS. 7 to 10, the directivity characteristic of the semiconductor light emitting device 10 forms a sawtoothed waveform in which the maximum peak and sequential peaks that are smaller than the maximum peak appear in the form of sawteeth (or ridges and valleys). The multiple peaks are generated by the scattering of light in the interface between the resin member 80 and the diffusing agent 82. In addition, the light scattering caused by the diffusing agent 82 may also cause the maximum peak position (maximum peak angle) to have an angle differing from the reference angle.

The sawtoothed waveform described above greatly differs from a waveform of a directivity characteristic observed by a typical LED. The directivity characteristic of the typical LED shows a smooth, curved parabolic line. Hence, the optical output of the LED has only one peak. In the first embodiment, the directivity characteristic of the semiconductor light emitting device 10 forms a sawtoothed waveform as shown in FIGS. 7 to 10. Thus, multiple peaks sequentially appear in addition to the maximum peak. The directivity characteristic forming such a sawtoothed waveform approximates a trapezoidal waveform in a range of the directivity angle. Therefore, the directivity characteristic of the semiconductor light emitting device 10 results in uniform light in the range of the directivity angle in comparison with the directivity characteristic of a typical LED showing a smooth parabolic line.

Relationship Between Mixture Ratio of Diffusing Agent 82 and Radiation Intensity of Semiconductor Light Emitting Device 10

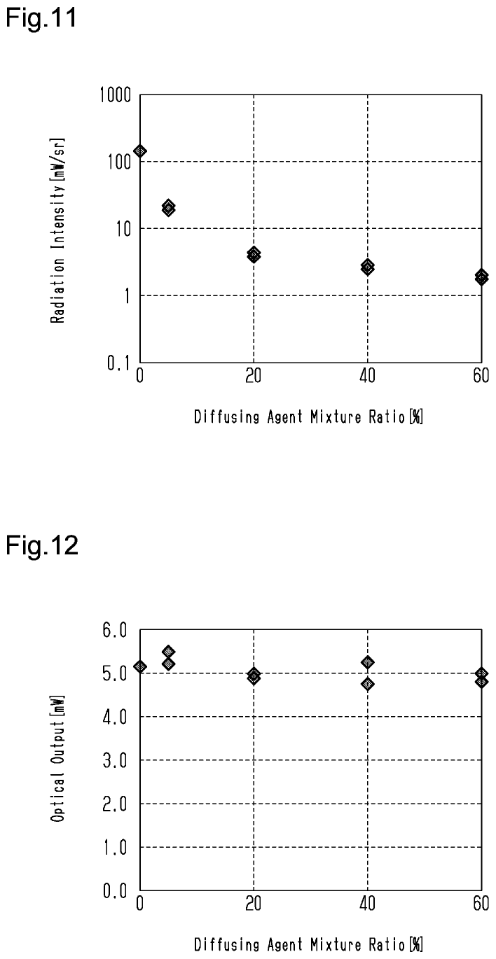

With reference to FIG. 11, the relationship between the mixture ratio of the diffusing agent 82 to the resin member 80 and the radiation intensity (mW/sr) of the semiconductor light emitting device 10 will be described. FIG. 11 shows the measurement results of the radiation intensity in the first to fifth samples with the mixture ratio of 0%, 5%, 20%, 40%, and 60% described with reference to FIGS. 6 to 10, respectively.

As shown in FIG. 11, as the mixture ratio of the diffusing agent 82 increases, the radiation intensity decreases. The third sample (mixture ratio of 20%), the fourth sample (mixture ratio of 40%), and the fifth sample (mixture ratio of 60%) have substantially the same radiation intensity. When the mixture ratio is in the range that is greater than or equal to 20% and less than or equal to 60%, the radiation intensity decreases slightly as the mixture ratio increases. Therefore, when the mixture ratio is selected in the range that is greater than or equal to 20% and less than or equal to 60%, while substantially the same radiation intensity is maintained, the relatively large directivity angle is set in a range of approximately 37 degrees (refer to FIG. 8) to approximately 88 degrees (refer to FIG. 10).

Relationship Between Mixture Ratio of Diffusing Agent 82 and Optical Output of Semiconductor Light Emitting Device 10

With reference to FIG. 12, the relationship between the mixture ratio of the diffusing agent 82 to the resin member 80 and the optical output (mW) of the semiconductor light emitting device 10 will be described. FIG. 12 shows the measurement results of the optical output in the first to fifth samples with the mixture ratio of 0%, 5%, 20%, 40%, and 60% described with reference to FIGS. 6 to 10, respectively.

As shown in FIG. 12, the first sample (mixture ratio of 0%), the second sample (mixture ratio of 5%), the third sample (mixture ratio of 20%), the fourth sample (the mixture ratio of 40%), and the fifth sample (mixture ratio of 60%) have substantially the same optical output. When the mixture ratio is in a range that is greater than 0% and less than or equal to 60%, it is not considered to cause any decrease in the optical output. Therefore, when the mixture ratio is selected in the range greater than 0% and less than or equal to 60%, while a satisfactory optical output is maintained, the directivity angle is set in a range that is greater than approximately 10 degrees (refer to FIG. 6) and less than or equal to approximately 88 degrees (refer to FIG. 10).

As described above, in the first embodiment, when the mixture ratio of the diffusing agent 82 to the resin member 80 is selected in the range that is greater than 0% and less than or equal to 60%, both the radiation intensity and the optical output are maintained. When the mixture ratio is selected in the range that is greater than or equal to 20% and less than or equal to 60%, the directivity angle is set to be even greater while both the radiation intensity and the optical output are maintained.

Increases in the mixture ratio of the diffusing agent 82 increase the viscosity of the resin member 80. The increase in the viscosity of the resin member 80 may cause formation of cracks or voids in the resin member 80. In this regard, the upper limit of the mixture ratio of the diffusing agent 82 may be limited to a predetermined value (for example, 60%). This limits increases in the viscosity of the resin member 80, thereby limiting formation of cracks and voids in the resin member 80.

The operation of the semiconductor light emitting device 10 of the first embodiment will now be described.

The semiconductor laser element 20 is configured as a VCSEL element and emits light in a direction substantially perpendicular to the front surface 20A (light outputting surface). The light emitted from the semiconductor laser element 20 enters the resin member 80, which covers the front surface 20A of the semiconductor laser element 20. The resin member 80 is mixed with the diffusing agent 82 at a predetermined mixture ratio. The diffusing agent 82 reflects (scatters) light in the interface between the resin member 80 and the diffusing agent 82 to diffuse the light in the resin member 80. This increases the directivity angle of the light when emitted from the upper surface 80T of the resin member 80 (ultimately, from the semiconductor light emitting device 10).

The semiconductor light emitting device 10 of the first embodiment has the following advantages.

(1-1) The semiconductor light emitting device 10 includes the semiconductor laser element 20, the light-transmissive resin member 80, covering the front surface 20A (light outputting surface) of the semiconductor laser element 20, and the diffusing agent 82 mixed into the resin member 80. With this structure, light emitted from the semiconductor laser element 20 is diffused by the diffusing agent 82. This increases the directivity angle of the light when emitted from the semiconductor light emitting device 10. Thus, the semiconductor laser element 20 obtains the directivity at the same level as that obtained from an LED. Typically, the semiconductor laser element 20 produces higher output and consumes less power than the LED. The semiconductor light emitting device 10 including the semiconductor laser element 20, having the advantages of high output and low power consumption, may be used for LED application. A typical LED device is provided with a light dispersing lens on a light outputting surface to increase the directivity angle. The semiconductor light emitting device 10 including the semiconductor laser element 20 dispenses with such a lens and increases the directivity using the diffusing agent 82. The semiconductor light emitting device 10 for LED application is smaller in size than the LED device.

(1-2) The diffusing agent 82 has a smaller thermal expansion coefficient than the resin member 80. In this case, the diffusing agent 82, mixed into the resin member 80, decreases thermal stress that occurs in the resin member 80 in comparison with when the accommodation portion 32 is filled with only the resin member 80. This limits breakage of the wires 26 or the like caused by thermal stress of the resin member 80.

(1-3) The semiconductor light emitting device 10 further includes the peripheral wall portion 44 surrounding the semiconductor laser element 20 and used as a reflector. The accommodation portion 32 of the semiconductor laser element 20 is defined by the peripheral wall portion 44 and filled with the resin member 80. With this structure, light refracted in the resin member 80 and scattered by the diffusing agent 82 is reflected by the peripheral wall portion 44 (reflector). This increases the efficiency of outputting the light from the upper surface 80T (light outputting surface) of the resin member 80.

(1-4) The semiconductor light emitting device 10 further includes the light diffusion plate 90 covering the upper surface 80T (light outputting surface) of the resin member 80. With this structure, when light is diffused by the diffusing agent 82 and emitted from the upper surface 80T of the resin member 80, the light is further diffused by the light diffusion plate 90. This increases the directivity angle of the light when emitted from the semiconductor light emitting device 10.

(1-5) The mixture ratio of the diffusing agent 82 to the resin member 80 is selected in the range that is greater than 0% and less than or equal to 60%. When the mixture ratio of the diffusing agent 82 is selected in this range, the directivity angle is increased while decreases in the optical output of the semiconductor light emitting device 10 are limited (refer to FIGS. 7 to 10 and 12).

(1-6) The mixture ratio of the diffusing agent 82 to the resin member 80 is selected in the range that is greater than or equal to 20% and less than or equal to 60%. When the mixture ratio of the diffusing agent 82 is selected in this range, the directivity angle is increased while a decrease in the optical output of the semiconductor light emitting device 10 is limited and a considerable decrease in the radiation intensity is limited (refer to FIGS. 8 to 12).

(1-7) The diffusing agent 82 is mixed into the resin member 80 to scatter light from the semiconductor laser element 20 to a position that differs from a peak position of optical output of the semiconductor laser element 20. In the first embodiment, the diffusing agent 82 scatters light from the semiconductor laser element 20 so that peaks of optical output of the semiconductor light emitting device 10 appear in a direction orthogonal to the front surface 20A (light outputting surface) of the semiconductor laser element 20 and an angular direction differing from the direction orthogonal to the front surface 20A. With the effect of the diffusing agent 82 for light scattering, light is uniformly emitted from the semiconductor light emitting device 10.

(1-8) In the first embodiment, the diffusing agent 82 is mixed into the resin member 80 so that the directivity characteristic of the semiconductor light emitting device 10 forms a sawtoothed waveform in which the maximum peak generated by the peak of optical output of the semiconductor laser element 20 and sequential peaks smaller than the maximum peak appear in the form of sawteeth (or ridges and valleys). The directivity characteristic forming such a sawtoothed waveform approximates a trapezoidal waveform in a range of the directivity angle. Therefore, uniform light is obtained in the range of the directivity angle as compared to the directivity characteristic of a typical LED.

(1-9) A VCSEL element is used as the semiconductor laser element 20. With this structure, the VCSEL element and the combination of the resin member 80 and the diffusing agent 82 replicate the directivity angle of an LED.

### Second Embodiment

A second embodiment of a semiconductor light emitting device 10 will now be described. To facilitate understanding, in the second embodiment of the semiconductor light emitting device 10, the same reference signs are given to those components that are the same as the corresponding elements in the first embodiment of the semiconductor light emitting device 10.

The semiconductor laser element 20 of the second embodiment differs from that of the first embodiment in far-field pattern (FFP). More specifically, the semiconductor laser element 20 of the first embodiment has a single-peak FFP (refer to FIG. 6). The semiconductor laser element 20 of the second embodiment has a multi-peak FFP. The remaining structure of the second embodiment is the same as that of the first embodiment. The semiconductor light emitting device 10 of the second embodiment also includes the semiconductor laser element 20, the resin member 80, and the diffusing agent 82. The semiconductor laser element 20 is, for example, a VCSEL as in the first embodiment. The materials, structures, and other characteristics of the resin member 80 and the diffusing agent 82 are the same as described in the first embodiment.

In the second embodiment, the resin member 80, which is mixed with the diffusing agent 82, has the role of changing the multi-peak FFP of the semiconductor laser element 20 into the single-peak FFP of the semiconductor light emitting device 10 and also changing light emitted from the semiconductor laser element 20 so that the directivity angle of the light is increased when emitted from the semiconductor light emitting device 10. Changes in the shape of far field pattern (FFP) of the semiconductor light emitting device 10 depend on the amount of the resin member 80 and the mixture ratio of the diffusing agent 82 to the resin member 80.

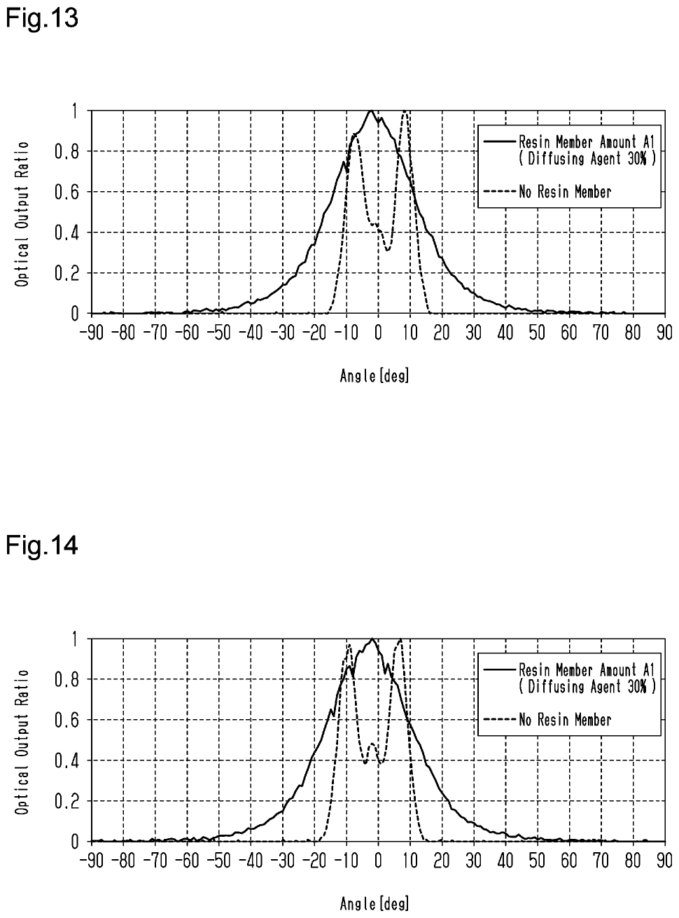

The directivity of the semiconductor light emitting device 10 of the second embodiment will now be described with reference to FIGS. 13 to 20. Four samples formed under different conditions that differ in the amount of the resin member 80 and the mixture ratio of the diffusing agent 82 will be described below. To distinguish from the first to fifth samples of the first embodiment, the four samples of the second embodiment will be referred to as the sixth to ninth samples. In the sixth to ninth samples, the semiconductor light emitting device 10 does not include the light diffusion plate 90 (refer to FIG. 2) so that the effects of the resin member 80 and the diffusing agent 82 are evaluated.

FIGS. 13 and 14 are each a graph (FFP) showing the directivity of the semiconductor light emitting device 10 in the sixth sample in which the amount of the resin member 80 is the first amount A1 and the mixture ratio of the diffusing agent 82 is 30%. FIG. 13 shows the directivity in the short-side direction of the semiconductor light emitting device 10 (Y-axis direction in FIG. 1). FIG. 14 shows the directivity in the long-side direction of the semiconductor light emitting device 10 (X-axis direction in FIG. 1). The first amount A1 refers to, for example, an amount of the resin member 80 filling the accommodation portion 32 to a position where the upper surface 80T of the resin member 80 is flush with the upper end surface 44T of the support 30. However, the upper surface 80T of the resin member 80 does not necessarily have to be a complete flat surface and may be slightly recessed.

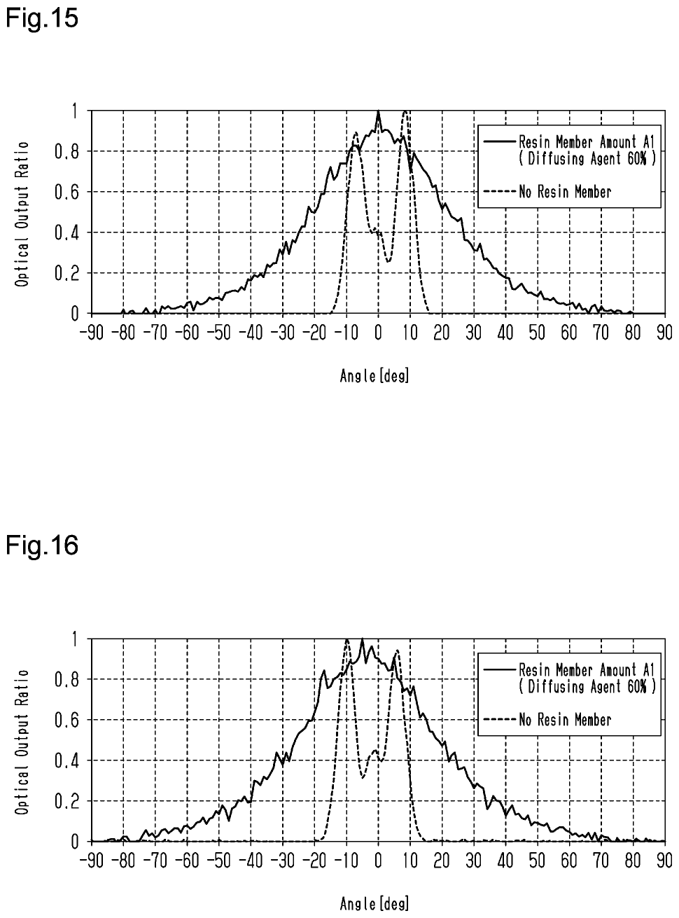

In FIGS. 13 and 14, the solid line indicates the directivity of the sixth sample. For comparison, the broken line indicates the directivity of a sample that does not include the resin member 80 (diffusing agent 82). That is, the broken line corresponds to the directivity of the semiconductor laser element 20. In FIGS. 13 and 14, the vertical axis indicates the optical output ratio of the semiconductor light emitting device 10 when the maximum value (maximum peak) of optical output of the semiconductor light emitting device 10 is 1.0. The same applies to the graphs in FIGS. 15 to 20, which will be described later.

As shown in FIGS. 13 and 14, the multi-peak FFP (broken line) of the semiconductor laser element 20 is changed to the single-peak FFP (solid line) in the sixth sample, which includes the resin member 80 and the diffusing agent 82. In addition, the directivity angle (half-power width) of the sixth sample is greater than the directivity angle of the semiconductor laser element 20 and is approximately 30 to 35 degrees in each of the short-side direction (FIG. 13) and the long-side direction (FIG. 14).

FIGS. 15 and 16 are each a graph (FFP) showing the directivity of the semiconductor light emitting device 10 in the seventh sample in which the amount of the resin member 80 is the first amount A1 and the mixture ratio of the diffusing agent 82 is 60%. FIG. 15 shows the directivity in the short-side direction of the semiconductor light emitting device 10 (Y-axis direction in FIG. 1). FIG. 16 shows the directivity in the long-side direction of the semiconductor light emitting device 10 (X-axis direction in FIG. 1). In FIGS. 15 and 16, the solid line indicates the directivity of the seventh sample. The broken line indicates the directivity of a sample that does not include the resin member 80 (diffusing agent 82), that is, the directivity of the semiconductor laser element 20.

As shown in FIGS. 15 and 16, the multi-peak FFP (broken line) of the semiconductor laser element 20 is changed to the single-peak FFP (solid line) in the seventh sample, which includes the resin member 80 and the diffusing agent 82. The directivity angle of the seventh sample is greater than the directivity angle of the semiconductor laser element 20 and the directivity angle of the sixth sample (FIGS. 13 and 14) in the short-side direction (FIG. 15) and the long-side direction (FIG. 16). This is considered to be because in the seventh sample, the mixture ratio of the diffusing agent 82 is increased from the sixth sample. In the seventh sample, the directivity is approximately 40 to 45 degrees in each of the short-side direction and the long-side direction.

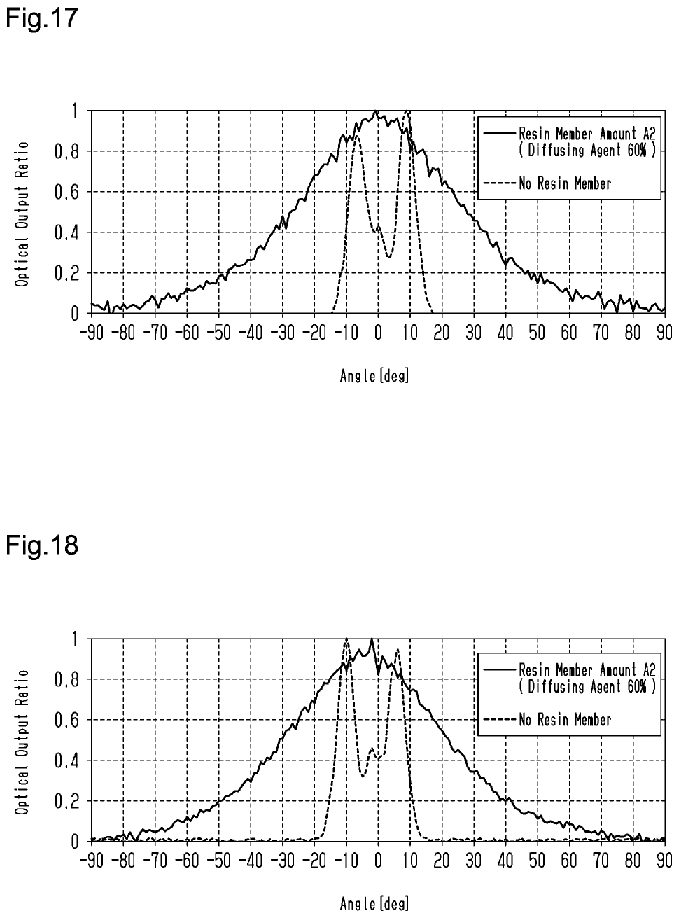

FIGS. 17 and 18 are each a graph (FFP) showing the directivity of the semiconductor light emitting device 10 in the eighth sample in which the amount of the resin member 80 is the second amount A2 and the mixture ratio of the diffusing agent 82 is 60%. FIG. 17 shows the directivity in the short-side direction of the semiconductor light emitting device 10 (Y-axis direction in FIG. 1). FIG. 18 shows the directivity in the long-side direction of the semiconductor light emitting device 10 (X-axis direction in FIG. 1). In FIGS. 17 and 18, the solid line indicates the directivity of the eighth sample. The broken line indicates the directivity of a sample that does not include the resin member 80 (diffusing agent 82), that is, the directivity of the semiconductor laser element 20. The second amount A2 is greater than the first amount A1.

As shown in FIGS. 17 and 18, the multi-peak FFP (broken line) of the semiconductor laser element 20 is changed to the single-peak FFP (solid line) in the eighth sample, which includes the resin member 80 and the diffusing agent 82. The directivity angle of the eighth sample is greater than the directivity angle of the semiconductor laser element 20 and the directivity angle of the seventh sample (FIGS. 15 and 16) in the short-side direction (FIG. 17) and the long-side direction (FIG. 18). This is considered to be because in the eighth sample, the amount of the resin member 80 is increased from the seventh sample. In the eighth sample, the directivity is approximately 50 to 55 degrees in each of the short-side direction and the long-side direction.

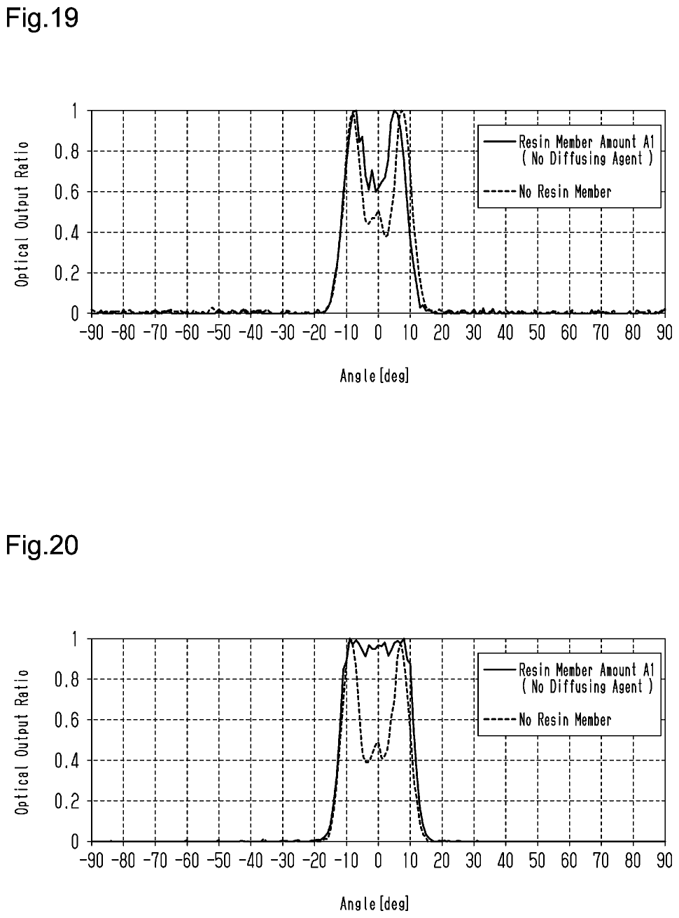

FIGS. 19 and 20 are each a graph (FFP) showing the directivity of the semiconductor light emitting device 10 in the ninth sample in which the amount of the resin member 80 is the first amount A1 with no diffusing agent 82. FIG. 19 shows the directivity in the short-side direction of the semiconductor light emitting device 10 (Y-axis direction in FIG. 1). FIG. 20 shows the directivity in the long-side direction of the semiconductor light emitting device 10 (X-axis direction in FIG. 1). In FIGS. 19 and 20, the solid line indicates the directivity of the ninth sample. The broken line indicates the directivity of a sample that does not include the resin member 80 (diffusing agent 82), that is, the directivity of the semiconductor laser element 20.

As shown in FIGS. 19 and 20, as compared to the semiconductor laser element 20 having the multi-peak FFP (solid line), the shape of the FFP (solid line) of the ninth sample has a slight tendency to change toward the single-peak FFP but practically has the multi-peak FFP. The directivity of the ninth sample is substantially the same as the directivity of the semiconductor laser element 20. The results indicate that the diffusing agent 82 has the effect of increasing the directivity angle.

The second embodiment of the semiconductor light emitting device 10 has the following advantage in addition to the advantages (1-1) to (1-9) of the semiconductor light emitting device 10 in the first embodiment.

(2-1) Even when the semiconductor laser element 20 has a multi-peak FFP, the semiconductor light emitting device 10 is changed to a single-peak FFP using the resin member 80 that is mixed with the diffusing agent 82. The mixture ratio of the diffusing agent 82 to the resin member 80 is increased to increase the directivity angle of the semiconductor light emitting device 10.

### Modified Examples

The embodiments described above may be modified as follows. The embodiments described above and the modified examples described below can be combined as long as the combined modifications remain technically consistent with each other.

The semiconductor laser element 20 is not limited to a VCSEL element and may be another semiconductor laser diode.

In the embodiments described above, the package structure is such that the semiconductor laser element 20 is mounted on the lead frame (conductive portion 50) but is not limited to one using a lead frame. In an example, a conductive layer may be formed on a ceramic substrate (or other insulative substrate), and the semiconductor laser element 20 may be mounted on the conductive layer. In another example, the semiconductor laser element 20 may be mounted on a printed circuit board (PCB). The package structure is not limited. Further, the semiconductor laser element 20 may be mounted together with another electronic component in a single package.

In the embodiments, the peripheral wall portion 44 is used as the reflector. However, the structure of the reflector is not limited.

The peripheral wall portion 44 does not necessarily have to be used as the reflector. That is, the peripheral wall portion 44 may be used as a simple wall.

The reflector may be omitted from the semiconductor light emitting device 10. In an example, the peripheral wall portion 44 (reflector) may be omitted, and the front surface 20A (the light emitting surface) of the semiconductor laser element 20 may be simply covered by a protruding portion of the resin member 80.

A multilayer resin structure may be formed from different resin materials and used instead of the resin member 80.

Two or more types of diffusing agents may be used instead of the diffusing agent 82.

The diffusing agent 82 may have a greater thermal expansion coefficient than the resin member 80. Even in this case, the effect of increasing the directivity angle is obtained in the same manner as the embodiments.

In the description of the embodiments, the mixture ratio of the diffusing agent 82 to the resin member 80 is greater than 0% and less than or equal to 60%. However, the upper limit of the mixture ratio is not limited to 60% and may be another value that is less than 100%.

The light diffusion plate 90 may be omitted from the semiconductor light emitting device 10.

The accommodation portion 32 (refer to FIGS. 2 and 3) may not be completely filled with the resin member 80. In an example, the resin member 80 may be separated by a gap from the light diffusion plate 90. The resin member 80 may be separated by a gap from the semiconductor laser element 20. The resin member 80 may be separated by a gap from another member (e.g., peripheral wall portion 44). The filling structure of the resin member 80 is not limited.

In the present disclosure, the term “on” includes the meaning of “above” in addition to the meaning of “on” unless otherwise clearly indicated in the context. Therefore, for example, the phrase “first component formed on second component” is intended to mean that the first component may be formed on the second component in contact with the second component in one embodiment and that the first component may be located above the second component without contacting the second component in another embodiment. In other words, the term “on” does not exclude a structure in which another component is formed between the first component and the second component.

The Z-axis direction as referred to in the present disclosure does not necessarily have to be the vertical direction and does not necessarily have to fully conform to the vertical direction. In the structures according to the present disclosure (e.g., the structure shown in FIG. 9), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

### CLAUSES

The technical aspects that are understood from the embodiments and the modified examples will be described below. The reference signs of the elements in the embodiments are given to the corresponding elements in clauses with parentheses. The reference signs used as examples to facilitate understanding, and the elements in each clause are not limited to those elements given with the reference signs.

A1. A semiconductor light emitting device (10), including:
a semiconductor laser element (20) including a light emitting surface (20A) from which a laser beam is emitted;
a light-transmissive resin member (80) covering the light emitting surface (20A) of the semiconductor laser element (20); and
a diffusing agent (82) mixed into the resin member (80).

A2. The semiconductor light emitting device (10) according to clause A1, further including:
a reflector (44) surrounding the semiconductor laser element (20), in which
the reflector (44) defines an accommodation portion (32) of the semiconductor laser element (20), and
the accommodation portion (32) is filled with the resin member (80).

A3. The semiconductor light emitting device (10) according to clause A2, further including:
a light diffusion plate (90), in which
the resin member (80) includes a light outputting surface (80T) located at an open end of the accommodation portion (32), and
the light diffusion plate (90) covers the light outputting surface (80T) of the resin member (80).

A4. The semiconductor light emitting device according to any one of clauses A1 to A3, in which a mixture ratio of the diffusing agent (82) to the resin member (80) is greater than 0% and less than or equal to 60%.

A5. The semiconductor light emitting device (10) according to clause A4, in which the mixture ratio of the diffusing agent (82) to the resin member (80) is greater than or equal to 20% and less than or equal to 60%.

A6. The semiconductor light emitting device (10) according to any one of clauses A1 to A5, in which the diffusing agent (82) is mixed into the resin member (80) to diffuse light from the semiconductor laser element (20) to a position that differs from a peak position of optical output of the semiconductor laser element (20).

A7. The semiconductor light emitting device (10) according to clause A6, in which the diffusing agent (82) is mixed into the resin member (80) so that a directivity characteristic of optical output of the semiconductor light emitting device (10) forms a sawtoothed waveform in which a maximum peak generated by a peak of optical output of the semiconductor laser element (20) and sequential peaks smaller than the maximum peak appear in a form of sawteeth.

A8. The semiconductor light emitting device (10) according to any one of clauses A1 to A7, in which the diffusing agent (82) scatters light from the semiconductor laser element (20) so that peaks of optical output of the semiconductor light emitting device (10) appear in a direction orthogonal to the light emitting surface (20A) and an angular direction differing from the direction orthogonal to the light emitting surface (20A).

A9. The semiconductor light emitting device (10) according to any one of clauses A1 to A8, in which the semiconductor laser element (20) includes a vertical cavity surface emitting laser (VCSEL) element.

A10. The semiconductor light emitting device (10) according to any one of clauses A1 to A9, in which the diffusing agent (82) is a silica filler.

A11. The semiconductor light emitting device (10) according to any one of clauses A1 to A10, in which the semiconductor laser element (20) has a single-peak far field pattern.

A12. The semiconductor light emitting device (10) according to any one of clauses A1 to A10, in which the semiconductor laser element (20) has a multi-peak far field pattern.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

What is claimed is:

1. A semiconductor light emitting device, comprising:
a semiconductor laser element including a light emitting surface from which a laser beam is emitted;
a light-transmissive resin member covering the light emitting surface of the semiconductor laser element; and
a diffusing agent mixed into the resin member.

2. The semiconductor light emitting device according to claim 1, further comprising:
a reflector surrounding the semiconductor laser element, wherein
the reflector defines an accommodation portion of the semiconductor laser element, and
the accommodation portion is filled with the resin member.

3. The semiconductor light emitting device according to claim 2, further comprising:
a light diffusion plate, wherein
the resin member includes a light outputting surface located at an open end of the accommodation portion, and
the light diffusion plate covers the light outputting surface of the resin member.

4. The semiconductor light emitting device according to claim 1, wherein a mixture ratio of the diffusing agent to the resin member is greater than 0% and less than or equal to 60%.

5. The semiconductor light emitting device according to claim 4, wherein the mixture ratio of the diffusing agent to the resin member is greater than or equal to 20% and less than or equal to 60%.

6. The semiconductor light emitting device according to claim 1, wherein the diffusing agent is mixed into the resin member to diffuse light from the semiconductor laser element to a position that differs from a peak position of optical output of the semiconductor laser element.

7. The semiconductor light emitting device according to claim 1, wherein the diffusing agent scatters light from the semiconductor laser element so that peaks of optical output of the semiconductor light emitting device appear in a direction orthogonal to the light emitting surface and an angular direction differing from the direction orthogonal to the light emitting surface.

8. The semiconductor light emitting device according to claim 1, wherein the semiconductor laser element includes a vertical cavity surface emitting laser element.

9. The semiconductor light emitting device according to claim 1, wherein the diffusing agent is a silica filler.
